(19) United States
(12) Patent Application Publication
(10) Pub. No.: US 2005/0208218 A1
(43) Pub. Date: Sep. 22, 2005

(54) Method for depositing boron-rich coatings

(75) Inventors: Richard C. Becker, Ipswich, MA (US); Stephen N. Bunker, Wakefield, MA (US)

Correspondence Address: Donald N. Halgren, 35 Central Street, Manchester, MA, 01944, US

(73) Assignee: IBADEX LLC., Danvers, MA (US)

(21) Appl. No.: 11/130,403

(22) Filed: May 16, 2005

Related U.S. Application Data
(63) Continuation-in-part of application No. 09/560,518, filed on Apr. 28, 2000.
(60) Provisional application No. 60/150,205, filed on Aug. 21, 1999.

(51) Int. Cl. C23C 14/32; C23C 16/00

(52) U.S. Cl. 427/248.1; 204/192.12; 204/192.16; 204/192.38; 427/446; 427/580; 427/585

(57) ABSTRACT

A method is disclosed for coating substantially pure boron or highly boron-rich borides in a controlled manner. Such a method of coating of boron has a variety of applications, including surface chemical and wear protection, neutron absorption, prevention of impurity emission from heated filaments and ion beams, elimination of metal dust from vacuum systems, boridizing, boron cluster emission, and reactive chemistry. Borides with a boron-to-metal ratio of 20 or more are known to exist and may be used as a feedstock for substantially pure boron coatings for deposition processes requiring feedstock electrical conductivity, and/or enhanced reactivity. While most metal borides coincidentally produce significant metal vapor as a by-product, certain borides of yttrium, holmium, erbium, thulium, terbium, gadolinium, and lutetium have been identified as capable of producing substantially pure boron vapor.

The present invention relates to a method for producing boron-rich coatings for a variety of uses related to surface protection, sputter targets, electrically conductive layers, semiconductor compatibility, neutron absorption, high temperature bonding, and reactive chemistry, and is a continuation-in-part application of co-pending non-provisional patent application Ser. No. 09/560,518, filed Apr. 28, 2000, which is based upon Provisional application Ser. No. 60/150,205, filed Aug. 21, 1999, each of which are incorporated herein by reference.

### FIELD OF INVENTION

### BACKGROUND OF INVENTION

Elemental boron is a well-known hard, covalent material. It also possesses considerable chemical resistance and is suitable for high temperatures in a vacuum or reducing atmosphere. It is known to impart considerable wear resistance to tooling materials if the boron can be added in sufficient quantity or coated on the workpieces. Unfortunately, elemental boron is difficult to deposit at a high rate by most commonly used deposition techniques, such as flame spray, plasma spray, or cathodic arc, because as a covalent material, it does not readily conduct electricity (resistivity ˜10¹⁴ microohm-cm).

Many boride compounds do conduct electricity very well. For example, metal boride compounds, such as TiB₂, VB₂, CrB₂, and LaB₆ have electrical resistivity in the range of 5 to 20 microohm-cm. However, these common boron compounds typically contain boron at a concentration only between 50 and 86 atomic %, and their use in a deposition process, such as plasma spray, would result in a coating containing a high concentration of the metal (14 to 50 atomic percent). It is possible to avoid the electrical conductivity problem by making use of the unusual properties of a novel class of metal boride compounds which typically consist of a single atom of a metal together with a large number of atoms of boron. There exist two major classes of such boron-rich borides, one based on 12 atoms of boron (92.3 atomic % boron) and the other based on 66⁺ atoms of boron (98.5⁺ atomic % boron). Examples include yttrium-12 boride (YB₁₂) and yttrium-66 boride (YB₆₆). The members of these classes of borides are usually electrically conductive yet substantially consist solely of boron. Examples of reported electrical conductivities exist for some borides with an atomic ratio of 12. The values are typically in the range of 10 to 25 microohm-cm. It is possible that other borides with even higher boron-to-metal ratios exist. For example, YbB₁₀₀ and YB₁₂₄₋₁₂₈ have been reported.

Within these classes, the vaporization properties of the metal component diverge into two groups, those in which the metal evaporates prior to the evaporation of the boron and those in which the boron evaporates prior to the metal component. If the former group is utilized in a high temperature deposition system, the boride feedstock may gradually become surface depleted in the metal component which was providing the electrical conductivity. If the deposition process is dependent on the conductivity, it may be gradually halted as the feedstock presents a surface of pure boron. If the latter group is used as a source for deposition of boron coatings, the resultant boron coating can be substantially pure and free of metal, but not necessarily conductive. Members of each group may be useful depending on the method of deposition and intended application.

Only a limited number of elements exist which have known compounds in which the boron-to-element atomic ratio is greater than or equal to 12. Compounds of the form MB₁₂ where M represents the element include, but are not necessarily limited to, Al, Dy, Er, Ho, Li, Lu, Mg, Np, Pu, S, Sc, Th, Th, Tm, U, Y, Yb, and Zr. Compounds of the form MB₆₆ where M represents the element include, but are not necessarily limited to, Dy, Er, Eu, Gd, Ho, Lu, Np, Pa, Pu, Sm, Th, Th, Tm, Y, and Yb. All of these latter elements are only in group 3A of the periodic table, which includes the rare earths, the lanthanides and the actinides. There have also been reported three other compounds with unusual boron-to-element atomic ratios, B₂₅N, NaB₁₅, NaB₁₆, and YbB₁₀₀. While most elements of the periodic table are known to make borides, only these elements produce highly boron-rich borides. There is also considerable overlap between the boride lists for 12 and 66 boron atoms. There are also a few examples of MB₁₂ in group 1A, group 2A, group 3A, group 3B, group 5A and group 6A of the periodic table. The only reported example in groups 4B, 5B, or 6B is ZrB₁₂.

The use of group designations used here is based on common American usage. The earlier nomenclature would be group 1B instead of 1A for the first column of the periodic table. The column containing yttrium and the rare earth elements is now 3B but used to be 3A. The IUPAC recommends that this column be designated 3, but this is not yet universally accepted.

Examples of the group in which the boron evaporates at a lower temperature compared to the companion element include the borides of yttrium, gadolinium, terbium, holmium, erbium, thulium, and lutetium.

In addition to the known examples of boron-rich boride compounds, it is also possible to dope boron with small amounts of elements that can affect the electrical conductivity. Doping is the dissolution of the element in the boron crystal, and unlike compound formation, does not require a specific stoichiometric ratio between the element and the boron. This is an alternative method for producing an electrically conducting boron material which consists substantially of the element boron. An impure sample of a boron-rich boride in which the stoichiometric ratio of the elements is somewhat different from that of a known compound may consist of a mixture of a known compound and doped boron material. “Boron-rich” defined as an atomic ratio of boron to all other elements, equal to 20 or greater. This covers a coating composed substantially of boron at slightly greater than 95 atomic percent, to define a purity range between metalurgical grade and high grade boron.

The known applications for inexpensive, easily deposited thick boron coatings are numerous. The general applications include, but are not limited to, those stated in the following list.

1) Electrically conducting coatings on electrical insulators and ceramics.

Using the method of plasma spray, boron-rich borides can be deposited onto a wide variety of ceramics and insulators including BN, Al₂O₃, aerogel, ZrO₂, quartz, and porcelain. Adhesion of borides to these materials, as well as to most metals, carbon, carbides, and nitrides is particularly strong. No substrate material has been encountered in which the plasma sprayed yttrium boride did not stick tightly to the surface, as long as the substrate is not thermally damaged by the deposition process.

2) Interior surfaces of semiconductor fabrication machines to minimize evolution of impurities.

Semiconductor wafers are particularly sensitive to impurity particles, such as metal dusts, that are deposited on wafers during a vacuum fabrication process. In order to avoid this phenomenon many semiconductor fabrication machines are now coated with silicon (not an impurity) on their interiors. The silicon is expensive to deposit over large areas and does not conduct electricity well, a problem leading to static charging of surfaces in processing equipment that employs charged particles. A thick conductive boron coating would avoid this problem, since boron is a natural dopant for silicon.

3) Boron-coated refractory hot filaments, such as tungsten, tantalum, or rhenium, to enhance electron output and minimize emission of metal vapor in high purity processing situations. See for example, U.S. Pat. No. 3,631,291 by Louis J Favreau which utilizes a conductive coating of LaB₆, which patent is incorporated herein by reference.

In some processing applications, particularly those for semiconductors, surface contamination from tungsten or tantalum impurities emitted from a nearby heated filament due to evaporation or sputtering is undesirable. A conductive boron-rich boride can be coated on such filaments using a method such as plasma spray. The resultant boron-rich coating readily emits electrons and substantially only boron vapor if the coating boride is selected from the group in which boron evaporates more readily than the metal. Since the coating is producing the electron emission, it is not necessary for the hot filament substrate to be a good electron emitting material. Other refractory materials, such as carbon, carbides, or nitrides, could be employed.

Coating technologies, such as plasma spray, can also produce free-standing filaments and heating elements without the requirement of a permanently attached substrate. The coating is built up into a mold, and when sufficient thickness is obtained, a mold release allows the removal of an independent, free-standing structure. This method permits the fabrication of a substantially pure boron filament without any contaminating substrate material.

4) Chemically resistant surface coating on containers.

Borides are well known to be highly resistant to many forms of chemical attack, particularly those due to high temperature molten metals, as long as a vacuum or reducing environment is maintained. Such chemically resistant surface coatings can be fabricated using a variety of well-known deposition techniques, such as salt bath, powder coating, chemical vapor deposition, and evaporation. See, for example, U.S. Pat. No. 4,536,224 by Beyer et al. for salt bath, U.S. Pat. No. 5,441,762 by Paul E. Gray et al. for coating with boride powder combined with chemical vapor deposition, U.S. Pat. No. 3,985,917 by Val J. Krukonis for chemical vapor deposition, and JP 10,068,069A by Satoru et al. for evaporation, each of which patents are each incorporated herein by reference. Electrically conductive boron-rich boride permits the use of a much broader selection of deposition methods which can be less expensive or more suitable for large area surface coating of such reaction crucibles and related apparatus.

Similar to the application example of refractory hot filaments, it is also possible to make a free-standing container of substantially pure boron by plasma spray coating a mold or mandril and subsequently separating the thick coating from the mold or mandril substrate.

Satoru et al. describe electric arc evaporative coating of borides in which the metal component of the boride is selected solely from Groups 4B, 5B, and 6B of the periodic table. Satoru et al. do not teach the advantages of selecting the ultra-high atomic percent borides that are found solely in Group 3B together with the rare earth elements for their application.

5) Wear and corrosion resistant coatings for tooling. See for example, U.S. Pat. No. 4,192,983 by Alfred J. Paoletti, incorporated herein by reference.

Boride coatings are known for their extreme hardness. Coatings can be applied to tooling by any of several techniques, such as plasma spray, and as stated in example 1) above, adhesion is sufficient to permit grinding and polishing into shape if required. It has also been demonstrated that in the presence of a diffusable layer of boron-rich boride, adhesion of materials as dissimilar as tantalum and graphite may be promoted. This property is of great significance for bonding tools to toolstocks and general refractory bonding technology.

Similar to the application example of refractory hot filaments, it is also possible to make a free-standing wear and corrosion resistant solid structure of substantially pure boron by plasma spray coating a mold or mandril and subsequently separating the thick coating from the mold or mandril substrate.

6) Addition of boron atoms or ions at or near the surface of a workpiece for hardening and wear resistance, commonly referred to as boridizing.

Boridizing (or boronizing) is a process of diffusing boron atoms into surfaces in order to increase hardness without substantially altering the shape of the substrate. Usually this is accomplished at high temperature with the source of boron atoms provided by a powder packed in close proximity to the surface to be treated. See for example, U.S. Pat. No. 4,011,107 by William J. Hayes, incorporated herein by reference. It is most commonly used with cutting tools. Other methods can be utilized to bring the boron atoms to the surface of the workpiece to be treated, including both vapor phase as well as ion phase. For example, a cathodic arc can transmit both coating and ions or if a mass filter is employed, it can transmit solely boron ions to the surface of the workpiece, where they are subsequently diffused into the volume thermally.

7) Thick coatings of neutron absorbing boron-10 isotope for use as a neutron shield or as a source of alpha particles produced in the absorption process.

Boron-10 is a well known isotope used for neutron absorption because of its high cross section. Coatings of boron, with or without isotopic enrichment of boron-10, can be applied to any substrate material compatible with nuclear reactors, fusion reactors, containment devices, or weapons, for use as a neutron shield. If plasma spray is employed, the boron coating can be made extremely thick in order to increase the effectiveness of the neutron absorption. It is also possible to combine a well-known neutron absorbing element with boron in a suitable boride. See for example, U.S. Pat. No. 5,273,709 by Danny C. Halverson et al., which is based on Gd combined with B₄C. Halverson et al. do not teach the advantages of selecting the ultra-high atomic percent borides that are found solely in Group 3B together with the rare earth elements for their application. These patents are also incorporated herein by reference.

8) Source for emission of clusters of boron atoms useful in space propulsion thrusters or ion sources.

Ion thrusters are currently used in space propulsion. Boron₁₂ ion clusters are the most common cluster species in the generated plasma. It has approximately the same mass as xenon, which is the heaviest noble gas available, and provides the greatest thrust. Being an electrically conductive solid state material, storage problems are eliminated, and potential energy per stored unit volume ratios increase significantly. Proper design engineering has demonstrated that after stable ignition has been established, the carrier gas may be eliminated and a self-sustaining discharge maintained.

9) Surface and/or bulk modification of metals, ceramics, and matrix materials.

The generated boron vapor may be introduced during fabrication, processing, and/or post-processing to modify properties of resultant materials. For example vapor or vaporizable material may be introduced into molten steel or other material at some state during the production process for purposes of altering hardness, chemical resistance, electrical properties, temperature resistance, etc. Boron is currently used in many of these areas. The novel properties of these boron-rich materials offer many valuable possibilities.

10) Protective coatings for fibers:

A common application is to coated the reinforcement fibers of composite materials with a boride compound in order to chemically protect the fiber from the corrosive molten binder material. See for example U.S. Pat. No. 5,354,615 by Tenhover et al., incorporated herein by reference. Tenhover teaches the use of boride coatings of Y, Sc, Gd, Tb, Dy, Ho, and Er of the chemical form RₓB₁₋ₓ, where x is from about 0.05 to about 0.66. This range of x is equivalent to a boron-to-metal atomic ratio of 19 to 0.5. Tenhover et al. do not teach the advantages of ultra-high boron-to metal atomic ratios in excess of 19, which produce a more boron-like coating than is possible with lower ratios.

11) Erosion-resistant coating

Boron and boride coatings are usually extremely hard. They have demonstrated usefulness for reducing the surface erosion caused by macro-particle bombardment. See for example, US Patent No. JP10148102A by Ikeda Kazuaki and Fujiwara Toshihiro, “Turbine Nozzle and Boride Covering Method Therefor”, 1998, incorporated herein by reference. Examples of applications include compressor and turbine blades, steam generator components, and slurry-handling devices.

Boron or borides have been successfully coated onto substrates by a variety of well known methods. The most commonly described coating techniques are thermally induced evaporation of the element or of various borides, thermal diffusion of boron atoms into a surface, sputtering of any of the common electrically conductive borides with a boron-to-metal ratio less than 12, chemical vapor deposition, and molten salt bath. Other techniques described involve a mixture of these techniques, such as the cementing of boron or boride power to a surface using a chemical binder combined with either chemical vapor deposition or thermal diffusion.

While these coating methods are compatible with the deposition of boron coatings, there exist a number of other commonly employed industrial coating techniques which offer various advantages in coating rate, ultimate coating thickness, or ultimate coating density. Magnetron DC sputtering of elemental boron is considered difficult, because the element is not electrically conductive and thus requires the far more inefficient method of RF or pulsed sputtering to frequently discharge the sputtering target. Similarly, plasma spray of elemental boron has been attempted on numerous occasions, but the high thermal stability of boron combined with the lack of electrical conductivity make the plasma stream very difficult to maintain and thus not commercially practical. Cathodic arc is another of the high throwing power industrial coating methods that does not perform well with elemental boron. Cathodic arc depends on making the feedstock of elemental boron the cathode of an anode-cathode arc discharge, and this requires electrical conductivity of the boron.

The methods of depositing boron may also be combined with the deposition of other coatings simultaneously as well as with the co-bombardment of energetic ions for enhancing the final density of the coating. Many other well-known combinations of deposition techniques exist which are compatible with the methods of depositing boron described herein.

Given that the boron precursor compound is electrically conductive, the following well known methods may be employed to deposit the coating. The advantage is that no special modification of the standard deposition technique is required to accommodate the electrically conductive boride.

1) Plasma Spray (also Flame Spray or Arc Jet):

Electrically insulating elemental boron does not coat well due to charging in the arc chamber, but metal borides behave more like metals during coating. The required metal boride feedstock is a powder which can be produced in very finely divided form. Powder is the most commonly available form of most of the borides. This technique has been studied for the widest range of substrates. Plasma spray is defined here to encompass a wide variety of processes that utilize electric arc or plasma heating of a stream of material which is then directed towards a workpiece to form a coating. The stream typically consists of a material which is a gas at room temperature combined with a sprayable solid at room temperature, such as a fine powder. Alternatively, the stream may consist of a material which is a gas at room temperature combined with a partially vaporized material which is normally a solid at room temperature, such as one or more electrically conducting rods. The many variations of this process have a wide variety of specialized names including, but not limited to, plasma spray, flame spray, thermal spray, vacuum arc spray, electric arc spray, arc spray, vacuum plasma spray, cold spray, low pressure plasma spray (LPPS), plasma torch, thermal plasma torch, plasma jet, arc jet, arc torch, arc plasma, flame gun, D-gun, twin wire arc, plasma vapor deposition, and HVOF. The process may optionally include a selection of the gas species, a selection of the temperature of the workpiece during material deposition, and/or a selection of the bias voltage applied to the workpiece during material deposition.

2) Cathodic Arc:

This method works only for electrically conducting feedstock, so boron is rarely deposited by this method at ths time. A solid target is required. The cathode may consist of a sintered boride cathode target, a melted boride powder, or a thick boride coating deposited onto a graphite or metal substrate by a technique such as plasma spray. Cathodic arc is defined here to encompass a wide variety of processes that utilize electric arc heating of a solid over sufficiently small areas to produce sufficient local heating to both vaporize the solid and cause the thermionic emission of large quantities of electrons. The resulting mixture of partially ionized vapor and uncharged particles impinges on a workpiece where a coating forms. The process may optionally include a selection of a carrier gas species and its ambient pressure, a selection of the temperature of the workpiece during material deposition, and/or a selection of the bias voltage applied to the workpiece during material deposition. When the temperature of the workpiece is elevated above 500° C. and preferably higher, the process may be referred to as boridizing, which includes the diffusion of boron atoms beneath the workpiece surface.

3) Cathodic Arc with Mass Filter:

This technique is useful for producing a high current of boron ions. Such a high current can be accelerated and impinged onto a workpiece. Such implanted ions may also be thermally diffused for boridizing the workpiece if the workpiece is maintained or post-processed at a sufficiently high temperature. Mass filtered cathodic arc is defined here to encompass a cathodic arc source combined with the addition of electric fields, magnetic fields, or both types of fields between the cathodic arc source and the workpiece such that the uncharged particulate or gas vapor material from the cathodic arc source is preferentially and substantially eliminated in the flux being transferred to form the coating. The process may optionally include a selection of a carrier gas species and its ambient pressure, a selection of the temperature of the workpiece during material deposition, and/or a selection of the bias voltage applied to the workpiece during material deposition. When the temperature of the workpiece is elevated above 500° C. and preferably higher, the process may be referred to as ion boridizing, which includes the diffusion of boron atoms beneath the workpiece surface.

4) Sputtering:

Elemental boron can be slowly sputtered using RF sputtering methods because it is an electrical insulator. However, the electrically conducting boride can be readily sputtered by the more efficient D.C. magnetron sputtering process or ion beam bombardment sputtering. Sputtering is defined here to encompass the class of coating processes that utilize ion bombardment of a source of material in order to dislodge and transfer individual atoms or clusters of atoms to a separate workpiece where a coating of the transferred atoms or clusters of atoms is accumulated. The many variations of this process have a wide variety of specialized names including, but not limited to, D.C. magnetron sputtering, R.F. magnetron sputtering, AC magnetron sputtering, ion beam sputtering, D.C. sputtering, RF sputtering, or pulsed sputtering. The process may optionally include a selection of an ambient gas species and its ambient pressure, a selection of the temperature of the workpiece during material deposition, and/or a selection of the bias voltage applied to the workpiece during material deposition. When the temperature of the workpiece is elevated above 500° C. and preferably higher, the process may be referred to as boridizing, which includes the diffusion of boron atoms beneath the workpiece surface.

5) Electric Arc Evaporation:

While elemental boron can be evaporated using electron beam or thermal boat evaporation methods, it is also possible to rapidly evaporate the metal boride using the heating produced as electric current flows through the solid boride. Electric arc is defined here to encompass the class of evaporative coating processes that utilize an electric arc discharge between anode and cathode electrodes in order to heat and vaporize either the anode or cathode or both as a source of material in order to transfer individual atoms or clusters of atoms to a separate workpiece where a coating of the transferred atoms or clusters of atoms is accumulated. Electrodes fabricated from an electrically conductive boride or boron-doped material can be utilized as an efficient source of boron vapor. The process may optionally include a selection of an ambient gas species and its ambient pressure, a selection of the temperature of the workpiece during material deposition, and/or a selection of the bias voltage applied to the workpiece during material deposition. When the temperature of the workpiece is elevated above 500° C. and preferably higher, the process may be referred to as boridizing, which includes the diffusion of boron atoms beneath the workpiece surface.

6) Resistive Evaporation:

The boride material has been pressed, sintered, crystallized, and plasma sprayed, as methods to create filaments and electrodes. Any of these methods may be employed to make resistance evaporation sources. Direct electrical heating is defined here to encompass the class of evaporative coating processes that utilize the resistive passage of electricity through an electrically conductive material in order to heat and vaporize the material in order to transfer individual atoms or clusters of atoms to a separate workpiece where a coating of the transferred atoms or clusters of atoms is accumulated. An electrode fabricated from an electrically conductive boride or boron-doped material can be utilized as an efficient source of boron vapor. The process may optionally include a selection of an ambient gas species and its ambient pressure, a selection of the temperature of the workpiece during material deposition, and/or a selection of the bias voltage applied to the workpiece during material deposition. When the temperature of the workpiece is elevated above 500° C. and preferably higher, the process may be referred to as boridizing, which includes the diffusion of boron atoms beneath the workpiece surface.

7) Photon- or Electron-Induced Evaporation:

Impingement of sufficiently energetic electrons or photons may easily be employed by traditional methods to create sufficient vapor for any of the instant applications. Photon-induced evaporation is defined here to encompass the class of evaporative coating processes that utilize photon-induced heating in order to heat and vaporize a material in order to transfer individual atoms or clusters of atoms to a separate workpiece where a coating of the transferred atoms or clusters of atoms is accumulated. Electron-induced evaporation is defined here to encompass the class of evaporative coating processes that utilize energetic electron beam-induced heating in order to heat and vaporize a material in order to transfer atoms or clusters of atoms to a separate workpiece where a coating of the transferred atoms or clusters of atoms is accumulated. An evaporative source fabricated from a boride or boron-doped material can be utilized as an efficient source of boron vapor. The process may optionally include a selection of an ambient gas species and its ambient pressure, a selection of the temperature of the workpiece during material deposition, and/or a selection of the bias voltage applied to the workpiece during material deposition. When the temperature of the workpiece is elevated above 500° C. and preferably higher, the process may be referred to as boridizing, which includes the diffusion of boron atoms beneath the workpiece surface.

These deposition processes may also co-deposit other materials with the boron in order to further modify properties for enhanced materials. For example, boron carbide (B₄C) is also a poor electrical conductor because it is covalently bonded. It is normally deposited using chemical vapor deposition. The addition of boron carbide powder and optionally fullerene carbon powder to the metal boride powder in plasma spray can allow the deposition of a boron carbide-like coating onto materials.

All of these applications and deposition techniques depend on the existence of an electrically conductive metal boride that consists of and can be deposited as substantially pure boron.

Ultra-high boron atomic ratio materials have been demonstrated to produce substantially pure monoatomic boron and boron cluster vapor when sufficiently energized. Under proper growth conditions wherein temperature, pressure, atmosphere, and electromagnetic fields may controlled, these vapors have been demonstrated to self-organize into various forms such as single and layered sheets, bundles of fibers, nanotubes of various kinds, spheres, and new crystaline forms such as B₃₂. These have been predicted to have desirable properties for applications in electronics, electro-optics, optics, nanofabrication, surface modification and alloying of metals and ceramics, and physio-chemical applications such as propulsion, energy storage, neutron attenuation, and alpha particle generation. Some of these materials have also demonstrated hydrophillic properties which are highly desirable for medical applications where a large neutron absorbing cross section is required.

These boron vapors are extremely reactive, demonstrating properties not evidenced in vapors derived from traditional boron-halide, -hydride, -carbide, -sulfide, -nitride, or -metal compounds. Early experiments have shown remarkable potential in wide areas of physical chemistry. By changing the background gas from inert to reactive, byproducts have been observed and analyzed, indicating that it is reasonable to expect new families of compounds in the carbides, hydrides, nitrides, halides, sulfides, and metals. Because of the novel physical and chemical properties of these vapors, it has also been possible to induce bonding of materials, such as tantalum and graphite, at temperatures well below what might be expected to be the temperature of what in this case would be TaC. Materials as dissimilar as zirconium oxide and molybdenum have been observed to bond in similar circumstances. The precursor material, when in the mixed vapor state, has been observed to adhere readily to Al, Al₂O₃, C, Si, SiO₂, W, Ta, Mo, steel, WC, Cu, aerogel, etc. The mechanism is believed to be some combination of physio-chemical boundary layering effects such that the boron vapor reacts with both surfaces to create the bond, in effect acting as a glue. Given the dissimilarity of materials so far tested, and the potential reactivity of boron, this would seem to indicate that novel compounds could be predicted for all materials but the noble gases, which simply facilitate the creation of new boron forms, which may each themselves have unique properties.

Alternatively, carbon fullerene vapors are combined with the above-mentioned boron vapors to form novel cluster and nanotube related structures. It is also predicted, that in the presence of sulfur, these boron and boron-carbon structures will take on properties conducive to the filling of the open volumes of the cluster and nanotube structures with different structures, for example nanotubes filled with spheres or solid material. Such materials would be electrically conductive and would potentially have use as feedstock material for any of the processes listed above.

The invention further includes:
1. A method of creation of targets for sputtering, cathodic arc, electron beam, and laser ablation processing.
2. A method of lining or fabricating free-standing refractory crucibles to protect from chemical attack.
3. A method of depositing the material on a removeable form for the creation of freestanding parts demonstrating the above-mentioned properties.
4. A method of making heating elements from these materials as coatings or freestanding parts.

Materials with boron ratios of 12 or greater may also be used for conductive coating purposes where the metal component volatilizes before or congruent with the boron fraction.

Examples of such materials may be found in different groups in the periodic table. The following list is intended to be exemplary, but not exhaustive. Group 2A: MgB₁₂, Mg₂B₁₄; Group 3B: ScB₁₂, LaB₆₆, NdB₆₆, SMB66, ThB₆₆, NpB₁₂, PuB₁₂, UB₁₂, AmB₁₂; Group 4B: ZrB₁₂, HfB₁₂; Group 5B: TaB₁₂; and Group 6B: MoB₁₂, WB₁₂.

### BRIEF SUMMARY OF THE INVENTION

It is therefore an object of this invention to provide a method for generating substantially pure boron which may be a useful source of coating material.

It is a further object of this invention to provide such a method for generating substantially pure boron such that the coating feedstock and the resultant coating are electrically conductive.

It is a further object of this invention to provide such a method for generating substantially pure boron such that extremely thick coatings can be obtained using well known coating technologies.

It is a further object of this invention to provide such a method for generating substantially pure boron such that the use of toxic chemicals may be avoided.

It is realized that the use of elemental boron as a feedstock in various well known coating technologies, such as cathodic arc, plasma spray, DC magnetron, electric arc, inductively heated evaporation, and electric current heated powder evaporation, does not perform reliably due to the lack of electrical conductivity and high thermal stability of elemental boron.

It is further realized that there exist metal boride compounds in which the companion metal represents less than 8 atomic percent of the compound.

It is further realized that said metal boride compounds are all electrically conductive.

It is further realized that when the companion metal does not readily vaporize, the metal remains present, permitting a gradual thermal decomposition through successive borides from a high boron-to-metal ratio towards the ratio of 4.

It is further realized that of the metal borides, only yttrium, holmium, erbium, thulium, terbium, gadolinium, and lutetium borides do not readily vaporize the metal component together with the boron.

The phase diagram of yttrium and boron is shown in FIG. 1. It shows that the higher boron-to-metal ratio borides decompose prior to melting. There exists a lower ratio boride that decomposes at a higher temperature in each case, thus indicating that there will be a successive loss of boron as a vapor with the next lower ratio boride as the decomposition product until YB₄ is reached. The phase diagram shows that YB₄ does not decompose in the solid state and is the most refractory of the several borides. Thus, it is the end product of the chain of decomposition. This interpretation of the phase diagram is confirmed experimentally by data presented in The Handbook of High Temperature Compounds (Kosalapova, 1990), pages 175-176, incorporated herein by reference. The table on these pages gives the measured vapor pressure of species resulting from thermal decomposition of most of the metal borides. It may be seen from the table that only only yttrium, holmium, erbium, thulium, terbium, gadolinium, and lutetium borides decompose to only pure boron vapor instead of metal and boron vapor. It may also be seen that only the hexaborides and the higher atomic ratio borides of these metals decompose in this manner.

The log of the vapor pressure of boron is given in the table only at 1823° K (1550° C.). When converted into millitorr units, the values for YB₆, HoB₆, and ErB₆ are 4.6, 34, and 56 millitorr. These values are typically quite temperature sensitive, increasing rapidly with greater temperature. These vapor pressure values are in the range suitable for use for physical vapor deposition and coatings.

The borides that have greater boron-to-metal ratios provide the greatest amount of boron vapor before the decomposition is halted at the tetraboride state. Thus, it preferable to use feedstock material that is as enriched as possible in the higher boron ratios and which has as little as possible of the lowest ratios, typically the diboride and tetraboride.

### DESCRIPTION OF THE DRAWINGS

Other objects, features and advantages will occur to those skilled in the art from the following description of a preferred embodiment and the accompanying drawings in which:

FIG. 1 is a copy of the phase diagram of yttrium and boron taken from the ASM Metals Handbook, volume 1, page 556, incorporated herein by reference.

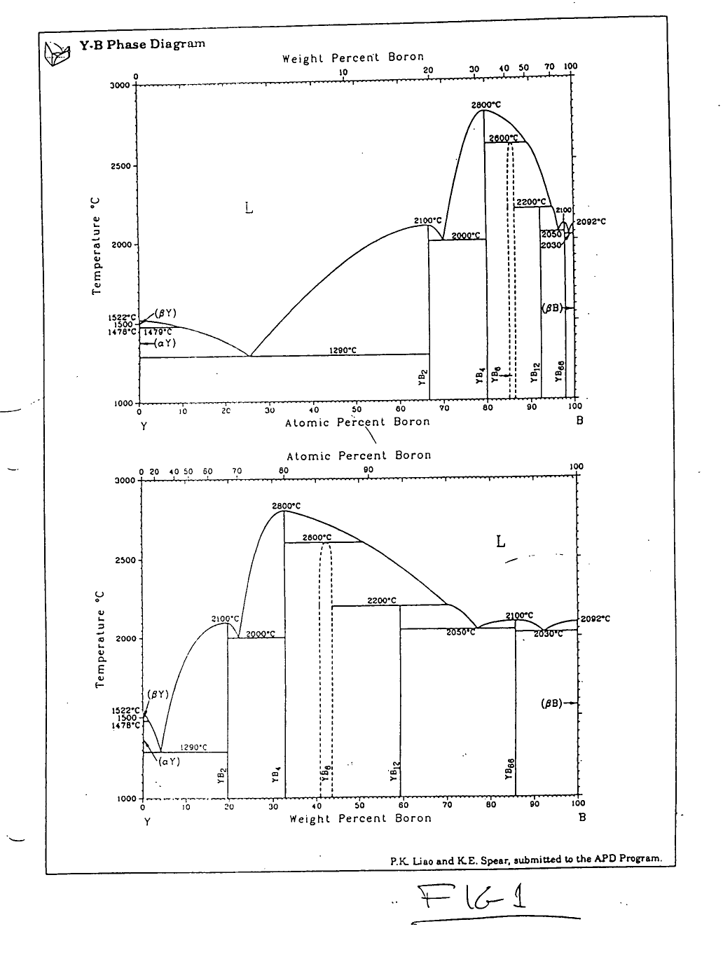

FIG. 2 is a copy of an EDAX measurement of the coating produced in EXAMPLE 5. The peak at the far left is due to boron coating. The other peaks are from the glass substrate.

### EXAMPLES AND DESCRIPTION OF THE PREFERRED EMBODIMENTS

### Example 1

YB₆₆ powder in the form of typically 50 to 75 micrometer particles has been used as the feedstock in an industrial plasma spray system utilizing argon gas as a carrier. The powder has been observed to spray easily and produce a characteristic granular deposit which can readily be built up to considerable thickness easily exceeding 3 mm. The deposit adheres readily to a wide variety of materials, including aluminum, steel, titanium, carbon, molybdenum, tungsten, tantalum, silicon, alumina, silica, zirconia, boron nitride, porcelain, and an aerogel foam. Good adhesion has been observed for all substrate materials tested. The resultant coating layer is extremely hard and difficult to break. In the case of a carbon substrate, for example, the graphite substrate will typically split or shatter prior to the debonding or failure of the coating. The coating has been rapidly deposited over large surface areas and surfaces with complex shapes using well known plasma spray methods.

### Example 2

YB₆₆ has been plasma spray coated onto a tungsten coil filament for use as an electron emitter in an ion source. In addition, other ion source components, including the molybdenum arc chamber walls and graphite electron repeller, have been similarly coated in order to produce an ion source with enhanced boron emission as well as to minimize the output of contaminating atomic species. The tungsten coil filament has been heated to near its normal operating temperature when only the tungsten surface is exposed, and the filament has been observed to produce electrons capable of sustaining the arc discharge of the ion source. The coating was found to melt at the operating temperature of the filament, but the liquid coating did not alter the electron emission properties. The coated filament was found to enhance the boron output of the ion source, and the coating was not observed to detract from the normal filament lifetime, and tungsten contamination of the plasma was significantly diminished. If a boride is taken from the list in which the boron vaporizes preferentially before the metal, for example YB₆₆, then there is little or no metal component in the resultant ion beam according to a magnetic mass analysis of the beam.

### Example 3

A DC magnetron sputter target has been formed using buildup of a 1.5 mm thick coating of YB₆₆ using plasma spray. The sputter target transferred boron at a rate which was approximately 10 times greater than from RF sputtering. Sputter targets have been made by coating on a backing of graphite, copper and other materials.

### Example 4

A cathodic arc cathode has been formed in a few minutes by plasma spray of YB₆₆ onto a graphite substrate. The coating was 3 mm thick. A cathodic arc system was operated with the said cathode at an arc current of nominally 50 Amperes in a background pressure of 10 millitorr of argon for 5 minutes. The output of the cathodic arc was directed towards a glass microscope slide target, and a grey, highly reflective boron-rich deposit was produced which was about 5 micrometers thick.

### Example 5

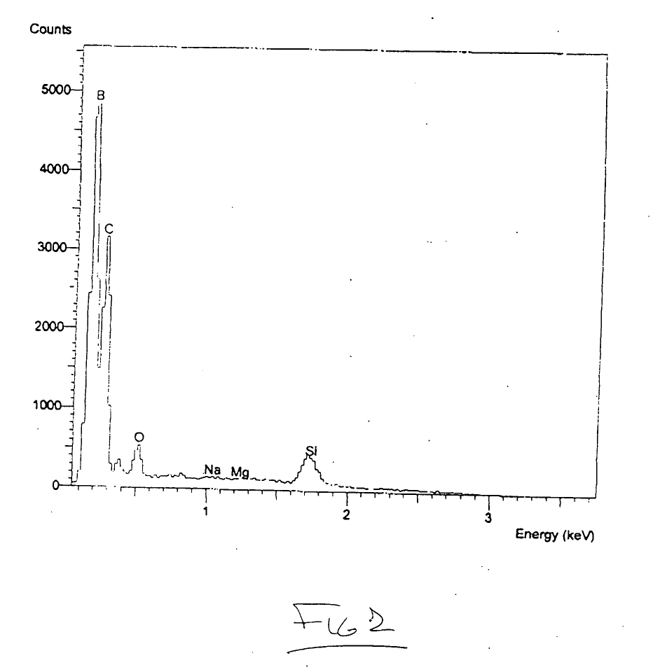

A high electric current of 75 Amperes has been drawn between two graphite electrodes connected by an excess of YB₆₆ powder while in vacuum. The powder was observed to melt and begin emitting boron vapor, which could be used to coat a glass slide test sample. The thickness of powder separating the electrodes has been up to 2.5 cm, demonstrating the electrical conductivity of the boride. A high coating rate of over 0.003 inches per minute at a distance of 2 inches from the evaporation source was observed. FIG. 2 shows an EDAX (energy dispersive analysis by X-ray) analysis of the resultant coating material. EDAX is insensitive to light elements, such as boron, so the boron peak observed at the far left in the mass spectrum appears unnaturally small compared to the background elements from the glass slide substrate.

### Example 6

Nanostructures of boron have been fabricated in the form sheets, coiled nanotube-like tubular sheets, and wire-like filament structures. The structures have appeared following operation of a plasma chamber using a nitrogen+hydrogen mixture known as forming gas. The types of structures varied with collecting surface temperature, which was typically in the range of 800 to 1000 degrees centigrade. The materials were hydroscopic which could be reversed in vacuum. The observed structures could change form following this process.

### Discussion of Certain Prior Art

The preset invention is novel unobvious over the prior art, specifically the Japanese reference of Kataoka (Ref. JP7-245409-A).

It is noted that the examiner's primary objection in this instance, was the fact that Kataoka mentioned the process of sputtering YB66 in the manufacture of a semiconductor device, while the present invention disclosure teaches that YB66 may be sputtered for the production of pure boron clusters. It will be demonstrated that even though the terms are used proximately in both circumstances, the physics and objectives of the present Becker et al application are entirely different, based upon highly specific research inventors have conducted on YB66 and closely-related materials over the course of many years. Inventor Becker holds U.S. Pat. No. 5,861,630, which is the foundation of this present application. It establishes a fundamental growth and breakdown method of these compounds, with the primary purpose of producing boron-clusters for ion implantation and other applications. U.S. Pat. No. 5,861,630 is concerned with the underlying physical mechanisms involved, because they are essential to a broad variety of scientific and industrial applications, where the many unique properties of the pure boron-clusters and their self-assembled allotropic forms, may be utilized to significant advantage.

The premise of this presentation is that what Kataoka teaches is entirely inconsistent with the findings and claims of Becker as clearly set forth in U.S. Pat. No. 5,861,630. It is essential to note at this point, that YB66, (used as a representative of the much larger “MB66” system), is a phase changing material, with no distinct demarcation point between phases. This is what makes it so useful, while making the explanation difficult and somewhat counter-intuitive. This present application is distinct from the issued precedent '630 patent, in that this is application oriented, based on a deeper understanding of the complex physics involved, which was completely unknown at the time of the previous '630 patent. It is believed that Kataoka's patent is referenced, based on a mis-understanding of this crucial principle, and a misunderstanding of the physics of sputtering. Kataoka's main concern and understanding is semiconductor device fabrication, and it is not to be expected that he would have any knowledge that the bulk properties of this exceptional material are not retained through the sputtering process. Gaining this understanding has been the sole purpose of inventor Becker's work over the course of many years of dedicated effort. Even at that, it has been very difficult work, primarily because the “MB66” family lies at the precise intersection of metals and ceramics, only now coming to be described as “Functionally Amorphous Materials” or “Metallic Glasses”, which have extraordinary properties unlike any other class of materials ever known. Much of the inventor's work was performed long before such a class had been identified, and systematic study undertaken by others.

“YB66” is formed in the Ibadex lab, by an oxy-thermal reduction of Y203 and BETA-RHOMBOHEDRAL elemental Boron. It must be made clear at this point that amorphous boron can not be used in the creation of the “MB66” family, because it can not change phase directly from amorphous to super-icosahedral. Only certain of the rare-earth species can be used as well, and grow to the MB>20 aka “MB66” structure. These are delineated in the previous '630 Becker patent. Closely related to this is the fact, (also noted in the previous patent), that this particular subset of rare-earth borides preferentially yields the boron clusters, whereas examples such as LaB6 remain covalent (LaB6>LaB4), until the metal atom is released, leaving only the non-conductive boron atom, which will not contribute to the DC plasma, RF must then be used, and the yields are substantially lower.

It has been calculated that during the extremely endothermic reduction/conversion process, each of the icosahedral boron clusters stores approximately 11.0 eV of energy. An icosahedral cluster of 12 atoms or larger is inherently unstable. It has been demonstrated in the Chemical Physics Letters 379 (2003) 282-286, S. J. Xu et al., entitled “Boron Cluster Anions Containing Multiple B12 Icosahedra”, and incorporated herein by reference in its entirety, that the clusters readily ionize to the 11B and 13B states, with relatively little external energy input to precipitate the fragmentation process and 5B is the most robust cluster size, forming a double pyramid. As clusters release and consume energy in a plasma, a broad population of cluster sizes is formed, and the number of any given size is proportional to the increasing instability as the clusters grow larger and larger. This can be seen in the a spectrum from the Ibadex ion beam-line, (which ion-beam line documentation is incorporated herein by reference in its entirety—Ibadex of Danvers, Mass. is the assignee of the present invention and the Becker et al '630 patent), which has a 70 degree electromagnetic sector magnet for discriminating the various species found in a plasma.

Fundamentally, all plasmas are based on some degree of sputtering, by definition. Sputtering is another term for the atomic or molecular ionization process of gaining or losing electrons. It is not specifically constrained to a particular type of equipment or process. The mechanism described in the abstract of the previous '630 Becker patent clearly enumerates an electrode substance material containing a mixture of boron atoms and metal atoms, as a means of introducing the boron into the plasma, from the solid state. This takes place in a condition of magnetic confinement, so as to maximize the collisions of atoms and electrons, to form the plasma. The Ibadex spectrum demonstrates beyond question that the YB66 plasma is primarily composed of monatomic B10 & B11 with significant peaks of 11B, 12B, 13B, 5B, and others. An insignificant peak of atomic Y is seen, contributing to the theory that it stays covalently bound at the core of the supericosahedral molecule. The “YB66” molecule therefore is shown to preferentially fraction, rather than stay intact. The binding energy of the YB core is infinitely larger than the binding energy of the supericosahedral molecule or individual clusters.

Mathematically it is therefore physically impossible to sputter a resultant coating of “YB66” onto a substrate. Furthermore, the electrically conductive boron clusters are anything but “oxidation resistant”, forming instead one of the best oxygen “getter” materials that could possibly exist. The literature and Ibadex experiments indicate that the bulk properties of “YB66” may theoretically have desirable properties such as the other materials claimed, SiC, Cubic SiC, BN, diamond, etc., which is most likely what the claim was premised on. Despite years of research physics on the material, and even more years than that in the semiconductor manufacturing industry, the inventor can think of no method, practical or otherwise, to deposit a covalent layer of “YB66” on to a semiconductor device. The other materials claimed remain either covalent throughout, (SiC, BN, etc,), or self-assemble into a regular crystalline structure, (diamond) from the vapor state.

It is hoped that this has demonstrated, if briefly, a modest degree of understanding by the author, of at least a few of the relevant properties of these “MB66” materials, and issues at hand in the case of the Kataoka patent. It is ironic that Ibadex, inventors' assignee, has been researching and developing these materials over the course of many years, initially as a superior method of implanting shallow layers of boron clusters into silicon, for the purpose of promoting N-type electrical activation in semiconductor devices, certainly not insulation. Yttrium would be an intolerable contaminant, which it is even more remarkable that it stays tightly bound to a YB4-YB6 core molecule.

The background has now been sufficiently established to address the issue of “double patenting”. Once again, these materials go through some rather ambiguous transitions, during assembly, and disassembly.

“MB66” polycrystal crystal is commonly zone-refined into a perfect single crystal, for research X-ray monochromators because it has an enormous 27 Angstrom lattice structure. Unless this is carefully done, a widely distributed population of stoichiometries will be found in any given sample. As noted earlier, some are much more likely than others, which is why “66” is usually used as a general designator for the distribution, in non-zone-refined material. This is very similar to the case of Fullerenes, where “C60” is often a generic designator for the distribution, unless special circumstances dictate more precision.

In similar fashion, Y is the most commonly cited example of a broad family of rare-earth borides, dealt with in the previous Becker patent. It is predicted that there will eventually be a systematized study of these materials, at which time the myriad stoichiometric combinations will each prove to have distinctive properties, just like the endless list of oxides, carbides, nitrides, etc. Until then, first-order generalizations will have to suffice. For example, HoBxx is predicted to have highly desirable magnetic properties, compared to the other family members. Once again, greater precision is not currently possible, so “YB66” and “MB66” must serve as the broadest of generalizations for this particular sub-group, as outlined in the previous patent, so the reader's understanding is requested for the time being. The considerable intervening study, has led to the conclusion that a broader mechanism may lie beneath what is known to date, and that it may therefore expand the list of metals far beyond the original. It is known that the “MB66” compounds have the ability to form what have been called “pseudo-binaries” where the RE/B molecule in the “core” does not get involved in any new reaction in a meaningful manner. In some ways, it acts somewhat like a catalyst, precipitating pure cluster formation, and unusual new compounds, such as B13C2, which spontaneously formed as cluster-vapor overflowed the crucible, then across a hot piece of graphite in the vacuum furnace during an “YB66” synthesis run. Many other such strange phenomena have been observed, but lack of resources precluded proper analytical work at the time.

In a related event, the hot vapor flowed between a piece of Ta shim stock, and a graphite plate, effecting a perfect functionally-graded bond that was stronger than the graphite itself, while the Ta remained ductile. The net effect was that while trying to take the two pieces apart at the points where they had joined, the graphite ripped out of the plate, rather than the bond giving way. This left small mounds of the graphite monolithically bonded to the Ta sheet, where it had ripped. Free valence electrons in the cluster-vapor had also turned the Ta bright gold, like TiN coatings.

In other cases, the vapor diffused into the surface of an available material, causing some unusual boride to form, effectively case hardening the surface, at an abnormally low bulk temperature, just as in the case of the bonding.

It is currently believed that this phenomenon is caused by the 11.0 eV energy released when the cluster fragments. This causes the temperature at the molecular level to be close to that of plasma, effecting whatever reaction is observed, while leaving the bulk temperature of the material at a relatively low level.

In a different energy regime, such as thermal plasma spray coating, the dwell time of the “MB66” molecule during the period of energy input is substantially less, therefore raising the temperature per molecule to a point that is insufficient to effect the previously described phase change. It is, however, sufficient to cause softening, or partial melting of the powder grain. This activates enough of the surface molecules to the fragmentation energy, so that the first few monolayers of the molecule become chemically reactive. When combined with the kinetic energy of the TPS process, enough energy is transferred to the first few monolayers of the substrate to achieve molecular bonding with the substrate. This may or may not be subsequently enhanced by heat treatment in order to precipitate the reaction further into the bulk material. The result is a monolithic functionally-graded peripheral alloy layer, transitioning to the properties of the bulk “MB66” at the surface.

This resultant may then be used for further purposes. One pending application is for surface alloying cutting tools, or bonding tools to tool posts. Diamond and ceramic materials are notoriously difficult to braze for this application. An easily bondable metal might receive boron-cluster treatment to harden the surface, or the functionally-graded bond described earlier might be effected. A pending application with the Air Force involves bonding a form-fitting Zirconia ceramic shell to the exterior surface of a Ta core, for hypervelocity kinetic kill-vehicles in the anti-ballistic missile program. Bearing surfaces and gears have been nitrogen treated for many years. Borodizing is a standard, but little-used variation of Nitriding. It typically involves gasses such as BF3 or BC13, which present significant problems such as toxicity and corrosion. The boron-cluster vapor/plasma is non-toxic, and may also be combined with gasses such as nitrogen, to form the variations of BN that are widely used in industry. Other combinations of gasses, vapors, plasmas, etc. are readily achievable, both in standard and non-standard stoichiometries. It can be readily inferred that these, and other properties, commend themselves to an entirely new and unanticipated industrial chemistry. The examples variously mentioned, are for illustrative purposes only, and not meant to define all the possibilities that will present themselves to those skilled in the industrial and scientific arts, as research continues, and more properties are discovered. The Ibadex list is far more comprehensive even at this point in time, but it is intended that these examples have been sufficient to communicate a minimal range of applications, as representative of the rest.

A distinction is thus shown between the first '630 Becker patent and the present application. The examples listed in the application had been observed, but until very recently, not fundamentally understood at all. It has been only during the prosecution of this application that the intuitive basis of the claims based on physical observations, have found any depth of explanation. This entire project has been like that. Intuition and study lead to strange observations that have immediate industrial applications, even though the mechanism behind the observations may remain unclear for some time thereafter.

This process is being altered by the growth of the knowledge base. The goal is to change the work from being explanatory, to being predictive. As unlikely as the circumstances are, this is developing into a major discovery. Historical examples clearly demonstrate that in such cases, early observations and patents are pitiful when compared to later developments that seem embarrassingly obvious in retrospect. This is what distinguishes this second invention from the first '630 patent, as clearly as current understanding allows.

In summation, Becker, (U.S. Pat. No. 5,861,630) teaches the foundational physical properties of these materials, while the present application represents subsequent intellectual and experimental findings of properties which lead to industrial and scientific applications that were completely unanticipated at the drafting and issuance of the fundamental '630 patent. This pattern is expected to continue and accelerate, making the findings reported here seem primitive by comparison.

1. A method for depositing a coating substantially composed of the element boron or an isotope of the element boron comprising the steps of:
i. Selecting a substrate for receiving said coating;
ii. Selecting an electrically conductive boron-rich feedstock in which the initial ratio of boron to a companion element is 20 or greater for said coating;
iii. Selecting a method for depositing said coating on said substrate from the group comprised of: plasma spray, cathodic arc, mass filtered cathodic arc, sputtering, electric arc, direct electrical heating, electron-induced evaporator, or photon-induced evaporation, and
iv. Depositing said coating on said substrate.

2. The method of claim 1 in which said electrically conductive boron-rich feedstock is comprised of a compound of boron.

3. The method of claim 2 in which said companion elements of said electrically conductive boron-rich feedstock is one or more selected from the group comprised of elements from group 3B of the periodic table, including the rare earth elements, the actinides, and the lanthanides.

4. The method of claim 2 in which said companion elements of said electrically conductive boron-rich feedstock is one or more element selected from the group comprised of hydrogen, lithium, carbon, sodium, magnesium, nitrogen, and sulfur.

5. The method of claim 1 in which said electrically conductive boron-rich feedstock consists of a doped solid solution of said companion elements within boron.

6. The method of claim 5 in which said companion elements of said electrically conductive boron-rich feedstock consists of one or more element selected from the group comprised of the transition metals and Group 3B elements, including the rare earth elements, the actinides, and the lanthanides.

7. The method of claim 1 in which said substrate is temperature-controlled.

8. The method of claim 1 in which said substrate is voltage-controlled.

9. A method for depositing a coating substantially composed of the element boron or an isotope of the element boron comprising,
i. Selecting a substrate for receiving said coating;
ii. Selecting an electrically conductive boron-rich feedstock in which the initial ratio of boron to a companion element is 20 or greater;
iii. Selecting a method for depositing said coating on said substrate from the group comprised of plasma spray, cathodic arc, mass filtered cathodic arc, sputtering, electric arc, direct electrical heating, electron-induced evaporation, or photon-induced evaporation;
iv. Selecting a carrier gas compatible with said feedstock and said method for depositing said coating;
V. Selecting the composition and pressure of gases in the environment of said substrate, and
vi. Depositing said coating on said substrate.

10. The method of claim 9 in which said electrically conductive boron-rich feedstock consists of a compound of boron.

11. The method of claim 10 in which the companion element of said electrically conductive boron-rich feedstock is one or more element selected from the group comprised of elements from group 3B of the periodic table, including the rare earth elements, the actinides, and the lanthanides.

12. The method of claim 10 in which the companion element of said electrically conductive boron-rich feedstock is one or more element selected from the group comprised of hydrogen, lithium, sodium, magnesium, nitrogen, and sulfur.

13. The method of claim 9 in which said electrically conductive boron-rich feedstock consists of a doped solid solution of companion elements within boron.

14. The method of claim 13 in which said companion elements of said electrically conductive boron-rich feedstock is one or more element selected from the group comprised of the transition metals and Group 3B elements, including the rare earth elements, the actinides, and the lanthanides.

15. The method of claim 9 in which said carrier gas is one or more element selected from the group comprised Group 8 inert gases, nitrogen, oxygen, methane, sulfur hexafluoride, sulfur dioxide, hydrogen, silanes, halogens, and hydrogen halides.

16. The method of claim 9 in which said gases in the environment of said substrate substantially excludes oxygen or water vapor.

17. The method of claim 9 in which said gases in the environment of said substrate comprise a chemically reducing atmosphere.

18. The method of claim 9 in which said gases in the environment of said substrate consist of a partial vacuum.

19. The method of claim 9 in which said substrate is temperature-controlled.

20. The method of claim 9 in which said substrate is voltage-controlled.
